(19) United States
(12) Patent Application Publication
(10) Pub. No.: US 2024/0057262 A1
(43) Pub. Date: Feb. 15, 2024

(54) Method and Plant for Producing Electronic Assemblies Using a Printing Device

(71) Applicant: Siemens Aktiengesellschaft, München (DE)

(72) Inventors: Matthias Heimann, Potsdam (DE); Carsten Borwieck, Berlin (DE); Ulrich Wittreich, Velten (DE); Stefan Nerreter, Heidesee OT Blossin (DE); Rüdiger Knofe, Teltow (DE); Peter Frühauf, Falkensee (DE); Rene Blank, Berlin (DE); Bernd Müller, Falkenberg (DE); Martin Franke, Berlin (DE)

(73) Assignee: Siemens Aktiengesellschaft, München (DE)

(21) Appl. No.: 18/257,074

(22) PCT Filed: Oct. 15, 2021
(86) PCT No.: PCT/EP2021/078555

§ 371 Date: Jun. 14, 2023

(30) Foreign Application Priority Data
Dec. 17, 2020 (EP) 20214817.7

(51) Int. Cl. H05K 3/12; H05K 3/00; H05K 1/03

(52) U.S. Cl. CPC H05K 3/1275; H05K 3/0005; H05K 1/0373; H05K 2203/0126

(57) ABSTRACT

Various embodiments include a method for producing electronic assemblies. The method may include: applying a fluid printing medium in a structured manner using a printing device multiple times consecutively in a sequential series of individual printing steps; measuring a rheological property of the printing medium in an automated repeated series of individual measurement steps during or between the individual printing steps; executing a computer-implemented rheological model for the execution of the individual printing steps, using the repeatedly measured rheological property as a variable input parameter; determining a favorable value for a selected printing parameter with the rheological model based on the currently measured rheological property; and automatically setting the determined favorable value for the selected printing parameter.

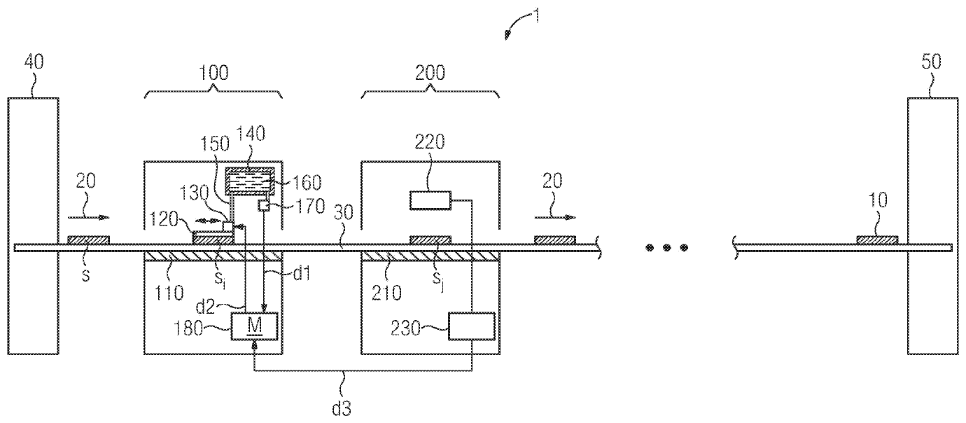

### CROSS-REFERENCE TO RELATED APPLICATIONS

This application is a U.S. National Stage Application of International Application No. PCT/EP2021/078555 filed Oct. 15, 2021, which designates the United States of America, and claims priority to EP Application No. 20214817.7 filed Dec. 17, 2020, the contents of which are hereby incorporated by reference in their entirety.

### TECHNICAL FIELD

The present disclosure relates to electronic assemblies. Various embodiments include methods and/or systems for producing electronic assemblies, in which a fluid printing medium is applied in a structured manner by means of a printing device.

### BACKGROUND

In this context, fluidic materials such as solder materials or sinter materials are particularly frequently printed in order to produce electrically conductive connections between the individual functional components and the conductors of an electrical circuit carrier. For this purpose, for example, solder pastes or sinter pastes are applied to a substrate in accord with a predefined layout. In a similar manner, other functional layers, such as, for example, adhesives, casting compounds or fillers, can also be applied in a structured manner to a carrier substrate in the context of electronics production. The electronic assemblies are usually produced in series, and therefore a large number of assemblies which are identical or similar to one another are processed one after the other in an automated production plant. For the printing process described, this means that a multiplicity of individual printing steps is carried out sequentially one after the other by the printing device.

One problem with these known production methods is that the predefined layout, i.e. the target structure for printing, cannot be exactly adhered to in practice. Rather, there are more or less slight deviations from the target structure in the individual printing steps. Particularly in the case of a multiplicity of printing steps carried out in succession, variations in external parameters (such as the temperature or the humidity of the ambient air) can result in fluctuations in the rheological behavior of the printing medium, which in turn can lead to fluctuations in the quality of the printed product. Thus, even in the case of an optimized setting of the printing parameters at the beginning of a production shift, drifting away from the optimum parameter set can occur in the course of time. And even if the external parameters are constant or are subject to only very slight fluctuations, it can be difficult to find the most favorable parameter set under the respectively prevailing equipment boundary conditions and for the respectively applicable target layout.

The teachings of the present disclosure include systems and/or methods for producing electronic assemblies which overcomes the disadvantages mentioned. In particular, the various embodiments provide that favorable values for one or more printing parameters can be found in a simple manner. In particular, simple, automated adaptation of this printing parameter during the operation of the production plant should also be possible.

As an example, some embodiments include a method for producing electronic assemblies (10) comprising: a) applying a fluid printing medium (160) in a structured manner by means of a printing device (100), wherein step a) is carried out multiple times consecutively in a sequential series of individual printing steps aᵢ), b) measuring at least one rheological property of the printing medium (160) within the printing device (100), wherein step b) is carried out in an automated repeated series of individual measurement steps bₙ) during the individual printing steps aᵢ) and/or between the individual printing steps aᵢ), c) providing a computer-implemented rheological model (M), in particular a computer-implemented rheological simulation model (M), for the execution of the individual printing steps aᵢ), wherein the rheological model (M) uses the repeatedly measured rheological property as a variable input parameter, d) determining a favorable value for at least one selected printing parameter with the aid of the rheological model (M) in accordance with the currently measured rheological property, and e) automatically setting the determined favorable value for the at least one selected printing parameter.

In some embodiments, the sequential series of individual printing steps aᵢ) a series of a plurality of individual substrates (s, sᵢ, sⱼ) is printed.

In some embodiments, the individual substrates (s, sᵢ, sⱼ) are electrical circuit carriers.

In some embodiments, the fluid printing medium (160) is a paste.

In some embodiments, the fluid printing medium (160) is a solder paste, a sinter paste, a casting compound, a filler or an adhesive.

In some embodiments, the fluid printing medium (160) contains metallic particles and additionally a liquid binder and/or an activator.

In some embodiments, the printing device (100) is a stencil printer, a screen printer, a pad printer or a dispenser.

In some embodiments, the at least one selected printing parameter is a squeegee speed, a squeegee force or a snap-off.

In some embodiments, the rheological property measured in the individual measurement steps bₙ) is a viscosity, a shear stress, a loss modulus and/or a storage modulus.

In some embodiments, the rheological property is measured with a process rheometer (170) integrated into the printing device (100).

In some embodiments, steps d) and e) are repeated multiple times.

In some embodiments, the determination of a favorable value in step d) is carried out in such a way that a target variable predicted with the aid of the rheological model (M) is optimized.

In some embodiments, the rheological model (M) provided in step c) is continuously adapted in that, following the individual printing steps aᵢ), a respective target variable for the printing result is measured and compared with the corresponding target variable predicted with the aid of the rheological model (M).

In some embodiments, the modelled and/or measured target variable is the accuracy of compliance with a predefined wetting area to be printed.

As another example, some embodiments includes a production plant (1) for producing electronic assemblies (10), designed to carry out one or more of the methods described herein, comprising a printing device (100) with a printing region (110) for receiving one or more substrates (s, sᵢ, sⱼ), which is designed to sequentially provide a series of a plurality of printing surfaces to be printed, a print head (130) for applying the printing medium (160), and a rheological sensor (170) for measuring the at least one rheological property of the printing medium (160) within the printing device (100), and further comprising a modelling unit (180), which is designed to provide a rheological model (M) for the execution of the individual printing steps aᵢ), wherein the rheological model (M) uses the repeatedly measured rheological property as a variable input parameter, an evaluation unit (180) for determining a favorable value for at least one selected printing parameter with the aid of the rheological model (M) in accordance with the currently measured rheological property and a setting unit for automatically setting the determined favorable value for the at least one selected printing parameter.

### BRIEF DESCRIPTION OF THE DRAWING

The teachings of the present disclosure are described below by means of an exemplary embodiment with reference to the attached drawing. Thus, the single FIGURE, shows a schematic illustration of a production plant 1 which is designed to carry out an example method incorporating teachings of the present disclosure.

### DETAILED DESCRIPTION

The methods and systems described herein may serves for the production of electronic assemblies. An example method comprises: a) applying a fluid printing medium in a structured manner by means of a printing device, wherein step a) is carried out multiple times consecutively in a sequential series of individual printing steps aᵢ), b) measuring at least one rheological property of the printing medium within the printing device, wherein step b) is carried out in an automated repeated series of individual measurement steps bₙ) during the individual printing steps aᵢ) and/or between the individual printing steps aᵢ), c) providing a computer-implemented rheological model for the execution of the individual printing steps aᵢ), wherein the rheological model uses the repeatedly measured rheological property as a variable input parameter, d) determining a favorable value for at least one selected printing parameter with the aid of the rheological model in accordance with the currently measured rheological property, and e) automatically setting the determined favorable value for the at least one selected printing parameter.

Step a) is therefore the actual printing step, in which the structured application of the printing medium takes place. In the automated series production of a multiplicity of electronic assemblies, this step a) is repeated multiple times in a sequential series, resulting in a series of individual printing steps aᵢ). For example, a plurality of substrates can be printed one after the other, and therefore the index i can be understood as the index of the respective current substrate. Each substrate to be printed can be used to produce an electronic assembly, for example. The sequential series of the individual printing steps aᵢ) can take place, in particular, with uniform, constant process timing.

Similarly, measurement of the rheological property in step b) is repeated multiple times during automated series production, and measurement is also carried out automatically. This is intended to be a case of “inline measurement”, which is carried out within the production plant and during series production. In particular, the frequency with which the individual measurement steps bₙ) are carried out can be derived from the process timing of the individual printing steps. For example, one or more measurements can be carried out for each printing step aᵢ). However, this is not absolutely necessary and it may also be sufficient if a new measurement step takes place only occasionally, i.e. for example after a fixed number of individual printing steps. Nevertheless, it is expedient if the measurement steps are also carried out with uniform and constant timing, and the timing (i.e. also the frequency) of the measurement steps is in a fixed whole-number ratio with the timing of the printing steps. In principle, the individual measurement steps bₙ) can be carried out during the printing steps or between the printing steps. Both are also possible, and it is thus possible, in particular, to measure the rheological property continuously.

The measured rheological property serves as an input parameter for a computer-implemented rheological model which is used to model the execution of the individual printing steps. In general, the rheological model is used to model a dependence of a target variable on a selected printing parameter for the respective value of the rheological property. This is therefore, in particular, a computer-implemented simulation model. This ensures that a favorable value for the selected printing parameter can be determined from the rheological model, namely by optimizing the value predicted by the model for the target variable (optionally taking into account relevant boundary conditions). Thus, with the aid of the model, an optimized value for the selected printing parameter, in particular, is obtained.

In principle, there can be a very large degree of variation in the complexity of the rheological model. In a very simple embodiment of the model, only one characteristic curve or one characteristic map is made available, which represents the predicted dependence of the target variable on the at least one selected printing parameter for the current value of the rheological property (and optionally further input parameters). In some embodiments, it can also be a more complex physical system model with which the influence of a multiplicity of parameters is simulated. The rheological model can also be implemented using an artificial intelligence method and, in particular, can have a neural network that can be trained by machine learning with the aid of training data.

In general, a favorable value for at least one printing parameter can be determined by combining the inline measurement of a rheological property and the use of a rheological model. In step e), the favorable value determined in this way can then be automatically adopted as a printing parameter for the respectively following process time. In this way, simple and automated optimization of one or more printing parameters can be accomplished. In particular, this optimization can take place continuously, so that, even in the event of a change in process parameters over time (for example a change in temperature or humidity or even a change in the printing layout), readjustment of the printing parameter is possible. In this way, automatic readjustment of the settings can be performed even when there are changes during a production shift. In this way, a consistently high quality of the print result is achieved and downtimes are avoided, which, in the case of purely manual adaptation, might sometimes be necessary for the reconfiguration of the relevant printing parameters if relatively large process fluctuations occur. Overall, therefore, it is thereby also possible to achieve an increased throughput of the electronic assemblies to be produced with a consistently high process quality.

A production plant incorporating teachings of the present disclosure is used for producing electronic assemblies and is designed to carry out one or more of the methods described herein. The advantages of the production plants described herein can be obtained by analogy with the advantages of the methods described above. Thus, the methods can be an automated production method in which the individual process steps are either completely automated or at least automated to such an extent that manual intervention is necessary only in exceptional cases (for example in the case of a fault).

The methods can be a method for series production, in which a series of mutually identical electronic assemblies is produced in accordance with the same layout. However, from time to time (for example within a production shift) there may be a changeover to another series, in which the layout parameters are changed. This may result, in particular in the individual printing steps aᵢ), in occasional changing of predetermined parameters such as printing layout and, where applicable, stencil type and the like. Particularly in the case of such a process changeover to another series or partial series, the method according to the invention enables simple automated adaptation and optimization of the at least one printing parameter to the new conditions.

It is thus possible in general, in the sequential series of individual printing steps aᵢ), to print a series of a plurality of individual substrates. In other words, it is then a process of series production in which a series of a plurality of individual substrates is printed one after the other in order in this way to enable a corresponding series of assemblies to be produced one after the other. As an alternative to such sequential loading of the printing device with individual substrates, however, it is also possible in principle for series production of a plurality of assemblies to be carried out in that a long substrate is printed by sequentially printing a plurality of successive printing surfaces on the same continuous substrate and these individual printing surfaces are separated into partial substrates only after the printing process. Such series production with a continuous substrate is expedient particularly in the case of flexible substrates with which a roll-to-roll process can be carried out.

In connection with the production of electronic assemblies, in some embodiments, the individual substrates are electrical circuit carriers. By printing these circuit carriers with structured functional layers, it is possible in a simple manner to implement a substep of the series production of such assemblies in which such a circuit carrier is the basic, mechanically load-bearing element, on which smaller subelements of the assembly are then placed. In general, such a circuit carrier can be an organic and/or an inorganic circuit carrier. As an example of a circuit carrier made of (at least partially) organic material, mention may be made here of commonly used printed circuit boards, which may in particular contain plastic layers. Ceramic substrates, for example, can serve as inorganic circuit carriers.

The fluid printing medium can be, in particular, a paste. In other words, it may be a suspension of a solid in a liquid, which is viscous on account of the solids content. When printing such a paste, the advantages described herein are particularly evident since here the optimum printing parameters depend in a particularly sensitive manner on the rheological properties of the printing medium. These rheological properties can also be variable with time. The paste can be a solder paste or a sinter paste, for example. A solder paste contains metallic solder particles as a suspension in a liquid binder. By means of a thermal soldering step following the printing step, the solder particles can be melted in order to produce an electrical and/or mechanical connection by means of the solder paste layer. In a similar manner, a sinter paste contains metallic sintered particles as a suspension in a liquid binder. By means of a subsequent thermal and/or mechanical sintering step, the sintered particles can be baked together to form a solid composite, thereby likewise forming an electrical and mechanical connection.

In some embodiments, however, the printing medium may also be a casting compound, a filler and/or an adhesive for the electronic assembly. These printing media may, in particular, comprise polymeric constituents. The casting compound used can be, for example, a casting resin with which electronic components can be encapsulated. In a similar manner, a filler can be used to underfill an electronic component in order in this way to bring about a thermally stable and, if appropriate, flexible mechanical connection to the substrate. This is also known as an “underfill”. In a similar, more general way, an adhesive applied in a structured manner can generally serve to permanently bond two or more subelements of the electronic assembly to one another materially in order in this way to achieve mechanical fixing.

In some embodiments, this can comprise metallic particles and additionally a liquid binder. Such a composition is expedient, in particular, in the case of the solder and sinter pastes described. The metallic particles provide the functionality in the production of a soldered or sintered connection, and the liquid binder enables the flowability or spreadability of the printing medium. The liquid binder may, for example, contain an organic solvent or oil and/or a low molecular weight organic resin. Optionally, an activator may additionally be included which, after activation, changes the properties of the printing medium. Thus, for example, a flux may be present as an activator, increasing the wetting of the substrate by the printing medium only after thermal activation.

In some embodiments, the printing device can be a stencil printer, a screen printer, a pad printer or a dispenser/jetter. Stencil printing and screen printing are particularly common methods for applying functional structured layers of solder or sinter pastes in electronics production, but other layers, such as, for example, adhesive layers, can also advantageously be applied in this way. In this case, a printing stencil or a printing screen serves as a structuring element. Pad printing and dispensing/jetting can also be used to advantage here since functional layers with a defined structure can also be applied by these methods. Therefore, dispensing is also to be understood as a printing method in the broader sense. Here too, the advantages described herein come into play since, in all the methods mentioned by way of example (as well as other known printing methods), the quality of the print result depends decisively on the rheological properties of the printing medium and selected printing parameters.

The at least one selected printing parameter for which a favorable value is determined in step d) and which is set automatically in step e) can generally be a printing speed or an outlet speed of the printing medium, a printing force or a distance of a printing head from the substrate surface. With respect to the methods of stencil or screen printing, this can be, in particular, a squeegee speed, a squeegee force or a snap-off. Within the scope of the invention, at least one such selected printing parameter is to be set on the basis of the rheological model. However, it is also possible and may be advantageous for a favorable value to be determined for two or more selected parameters in step d) and for this value to be set in step e). In this way, printing results that are optimized to a particularly great extent can be achieved.

In some embodiments, the rheological property measured in the individual measurement steps bₙ) can be a viscosity, a shear stress, a loss modulus and/or a storage modulus. These rheological properties are, in principle, relatively easy to measure and they have a comparatively great influence on the specific printing parameters with which a qualitatively good print result can be achieved. In particular, the wetting of the substrate with the printing medium effected during a printing step is highly dependent on these rheological properties on the one hand and on the selected printing parameter on the other hand.

In some embodiments, the rheological property can be measured with a process rheometer integrated into the printing device. In other words, this is intended to be a rheometer which can measure the rheological property “in situ” within the printing device, eliminating the need to remove a sample from the plant in order to carry out the measurement. An example of such “inline rheometers” that may be mentioned here are those referred to as process viscometers, which can be integrated into a pipeline or into a storage vessel and can measure the viscosity of an operating medium “in situ” there. Possible locations for such a rheological inline measurement are, for example, a storage vessel for the printing medium, a feed line of the printing medium to a print head or else a location in the region of the print head itself. These three variants of the method correspond to three analogous variants of the production plant in which the rheological sensor is integrated either into a storage vessel or into a feed line or into the print head. A rheological sensor in a storage vessel can be implemented, for example, by a measuring stirrer.

In some embodiments, steps d) and e) can each be repeated multiple times. In other words, the determined favorable value for the selected printing parameter is then not only set once but is repeatedly adapted to the respectively prevailing boundary conditions during the series production of the assemblies.

The determination of the “favorable value” in step d) can generally be accomplished by optimizing a target variable predicted by the model or, at least within certain limits, by bringing it as close as possible to an optimum value. This modeled target variable can generally be a characteristic quality variable of the printing process, in particular the accuracy of compliance with a predefined wetting area to be printed. In other words, a contour fidelity can be used here as a target variable, where the target variable can be, on the one hand, compliance with the size, but, on the other hand, above all, also with the shape of the predefined wetting area. For this purpose, for example, an averaged deviation of a real printing contour (that is to say the boundary line between the printed and non-printed surface) and a predefined desired contour can be determined and minimized. Such an averaged deviation is not limited to an arithmetic mean; on the contrary, it is also possible for a weighted average to be determined and minimized, for example using a root mean square value.

As already described, optimization can involve the use of either a simple characteristic curve or a characteristic map or else a more complex model having a multiplicity of dependencies, right up to a self-learning neural network. In the latter case, it is also possible, in particular, for measured values for the quality parameter from a downstream measurement of actually performed printing steps to be used as part of a training data set.

In some embodiments, this can use one or more further input parameters, for example an ambient temperature and a humidity of the surrounding air, in addition to the measured rheological property. These further parameters can be continuously updated, in particular as a function of measurements carried out “in-line” during the process. Further input parameters, which can either be constant over a production series or can optionally also be varied, at least within a production shift (that is to say, for example, from partial series to partial series) are the type (that is to say material and/or geometry) of a printing stencil used, a printing screen and/or a squeegee. In the case of the printing stencil or the printing screen, for example, the size, number and density of the individual printing openings can be varied between different partial series, and this also has an influence on the print result and can lead to adjustments in the selected printing parameter.

In some embodiments, the rheological model provided in step c) can be continuously adapted in that, following the individual printing steps aᵢ), a respective target variable for the printing result is measured and compared with the corresponding target variable predicted with the aid of the rheological model. That is to say, it is possible, in particular, for a plurality of additional measurement steps fᵢ) to be performed, which are carried out in a downstream process device. This downstream process device can be, in particular, an optical inspection device, particularly a solder paste inspection device.

In some embodiments, quality monitoring takes place within the plant and a closed control loop for the rheological model is provided by the additional measurement steps. The additional measurement results are used to adapt the model, which significantly improves the result of its prediction and the optimization of the selected printing parameter carried out with it. Accordingly, a correlation of fluctuations in the rheological measured variable in the measurement steps bₙ) with fluctuations in the additional measured variable in the subsequent control steps fᵢ) is also taken into account in this closed control circuit. By appropriately optimized adaptation of the selected printing parameter, the overall fluctuations in the print quality obtained are kept as small as possible.

The target variable or characteristic variable measured in the subsequent control steps fᵢ) can in turn be, in particular, a wetting angle or the accuracy of compliance with a predefined wetting area. In principle, the adaptation of the rheological model can be accomplished in different ways: in a first variant, further physical parameters can be adapted within the rheological model. These can be, in particular, those physical parameters which are subject to fluctuations and/or for which no exact measured values are known. In this way, fluctuations in temperature and/or humidity can be detected at least approximately via their effect on the print quality.

In some embodiments, however, it is also possible to change the model itself, that is to say, in particular the underlying calculation method. This can be used, in particular, if within the model an artificial intelligence method is used. Thus, for example, a neural network with measured data from the following control steps fᵢ) can be trained or further optimized as the process continues.

In some embodiments, the production plant can also have an inspection device downstream of the printing device, by means of which the additional measurement can be carried out in the subsequent control steps fᵢ). In particular, this can be a solder paste inspection device.

In some embodiments, the printing region of the printing device can be, in particular, a printing table which is designed for sequentially receiving a plurality of substrates. The printing device can optionally comprise a structuring element such as a printing stencil or a printing screen.

In some embodiments, the modeling unit described and the evaluation unit of the production plant do not have to be part of the printing device, but they can be integrated therein. The modeling unit and the evaluation unit can be combined in a combined simulation unit which is designed, in particular, for carrying out computer-aided modeling and evaluation. The setting unit described is expediently integrated into the printing device.

The production plant 1 serves for the automated series production of a multiplicity of electronic assemblies 10. These assemblies 10 are produced by conveying a multiplicity of corresponding substrates s along a process direction 20 through the plant. For this purpose, a conveying device 30 is provided, which transports the individual substrates s from an input stacker 40 to an output stacker 50. In the region of the input stacker 40, the substrates are still bare electrical circuit carriers. In the region of the output stacker, on the other hand, these are finished electronic assemblies 10, which, in particular, can be equipped with a multiplicity of electronic components and can be electrically connected.

Between the input stacker 40 and the output stacker 50, the substrates s to be processed pass through a plurality of process devices, of which only one printing device 100 and one optical inspection device 200 are illustrated here. Following the inspection device 200, a number of further process devices are expediently arranged, through which the substrate passes. Since these are less relevant in connection with the present invention, they are represented here only in consolidated form by three points. In this region, the production plant can also comprise, for example, a loading device and a reflow soldering system.

Within the printing device 100, in each case one layer of a fluid printing medium 160 is applied in a structured manner to the individual substrates s. For this purpose, the printing device 100 contains a storage container 140 holding this printing medium. The printing medium can be, for example, a solder paste or a sinter paste. The printing device 100 can be, for example, a stencil printer.

In the example shown, the printing device 100 has a printing table 110, on which the respective substrate (here sᵢ) to be printed is arranged and processed during the printing step aᵢ) currently to be carried out. Thus, in particular, a plurality of such substrates are coated in a structured manner in a sequential series of individual printing steps aᵢ). In the present example of the stencil printer, the structure is defined by means of a printing stencil 120, which is placed on the respective substrate before printing. The printing medium is then applied via a print head 130, which is designed here, for example, as a closed squeegee head unit. This printing unit is fed with the printing medium 160 from the storage container 140 via a feed line 150. The horizontal movement of the squeegee head 130 during the printing process is indicated by a double arrow.

In some embodiments, a rheological sensor 170 is arranged within the printing device 100. This is, in particular, an integrated process rheometer which can measure a rheological property of the fluid printing medium within the printing device 100 without the need for separate sampling. In the example shown, the rheometer 170 is arranged in the region of the storage container 140. In some embodiments, it could also be arranged, for example, in the region of the feed line 150 or in the region of the squeegee head 130.

With the rheological sensor 170, a rheological property of the printing medium 160 (for example, a viscosity) is measured repeatedly and, in particular, continuously. Thus, a series of individual measurement steps bₙ) is carried out, it being possible for the timing of these measurement steps bₙ) to be coupled, in particular, to the timing of the individual printing steps aᵢ). However, the frequency of measurement does not have to be identical with the printing frequency; it can be, for example, a whole-number multiple or a whole-number fraction of the printing frequency.

The individual measured values for the rheological property are transmitted by the sensor 170 to a combined modeling and evaluation unit 180, this data flow being denoted here by d1. In the modeling and evaluation unit 180, a rheological model M is provided, by means of which a favorable value for at least one selected printing parameter is determined. In this determination, in addition to the measured rheological property, further input parameters can play a role, for example a measured or modeled ambient temperature or atmospheric humidity and/or relevant parameters of the device such as the material or geometry of the printing stencil 120 and/or of the squeegee head system 130. In any case, a favorable value for the selected printing parameter is determined with this model M, and this value is transmitted back to the movable part of the printing device. This transmission of the favorable printing parameter is denoted here by d2. The value is transmitted, for example, to the squeegee head system 130, where the printing parameter is set to the determined favorable value by means of a setting unit (not illustrated separately here). In this way, an adapted and optimized printing parameter can be used in the printing of the following substrate s. As a result, the quality of the print result can generally be improved and, in particular, quality losses due to fluctuations in the environmental parameters can be avoided or at least mitigated by the continuous measurement of the rheological property and a continuous recalculation and readjustment of the selected printing parameter.

In some embodiments, the quality of the print result is monitored in a subsequent process step, and a measured characteristic variable is transmitted back to the printing device 100. This is shown here by way of example on the basis of the following optical inspection device 200, which can be, in particular, a solder paste inspection device. This device 200 has an inspection table 210, on which the respective substrate sⱼ to be inspected is arranged during measurement. Arranged above this table 210 is an optical measuring system 220, by means of which one or more characteristic quality variables of the print result can be measured.

These measured characteristic variables are optionally stored in a data storage device 230 and in any case transmitted back to the printing device. This data flow is denoted here by d3. The optical measurement of this characteristic variable is also carried out repeatedly and, in particular, is carried out following the printing step for each substrate s to be processed. The feedback d3 of the data provides a closed control loop since the optical characteristic variables are used as an additional input in the rheological model M in order to provide an even better result in the next determination of a favorable value for the selected printing parameter. Such an adaptation can be carried out either by a change to the modeling method itself and/or by adaptation of assumptions about further parameters (such as temperature or humidity). In any case, in this variant with a closed control loop, an additional optimization of the printing parameter is achieved as a function of the actually achieved print quality, wherein the continuously measured rheological property is taken into account within the model. With the model, it is then also possible, in particular, to correlate temporal variations in the measured rheological property with temporal variations in the print quality achieved, and, taking this correlation into account, even better continuous adaptation of the selected printing parameter can be achieved.

### LIST OF REFERENCE SIGNS

1 Production plant
10 Electronic assembly
20 Process direction
30 Conveyor device
40 Input stacker
50 Output stacker
100 Printing device
110 Printing table
120 Printing stencil
130 Print head
140 Storage container
150 Feed line
160 Printing medium
170 Rheometer
180 Modelling and evaluation unit
200 Solder paste inspection device
210 Inspection table
220 Optical measuring system
230 Data storage device
d1 Transmission of the rheological measurement data
d2 Transmission of the favorable printing parameter
d3 Transmission of the optical measurement data
M Rheological model
s Substrate
sᵢ Substrate with index i
sᵢ Substrate with index j

What is claimed is:

1. A method for producing electronic assemblies, the method comprising:
a) applying a fluid printing medium in a structured manner using a printing device,
wherein a) is carried out multiple times consecutively in a sequential series of individual printing steps aᵢ);
b) measuring a rheological property of the printing medium within the printing device,
wherein b) is carried out in an automated repeated series of individual measurement steps bₙ) during the individual printing steps aᵢ) and/or between the individual printing steps aᵢ);
c) executing a computer-implemented rheological model for the execution of the individual printing steps aᵢ),
wherein the rheological model (M) uses the repeatedly measured rheological property as a variable input parameter;
d) determining a favorable value for a selected printing parameter with the rheological model based on the currently measured rheological property; and
e) automatically setting the determined favorable value for the selected printing parameter.

2. The method as claimed in claim 1, wherein in the sequential series of individual printing steps aᵢ), a series of individual substrates is printed.

3. The method as claimed in claim 2, wherein the individual substrates each comprises an electrical circuit carrier.

4. The method as claimed in claim 1, wherein the fluid printing medium comprises a paste.

5. The method as claimed in claim 1, wherein the fluid printing medium comprises at least one of: a solder paste, a sinter paste, a casting compound, a filler, or an adhesive.

6. The method as claimed in claim 1, wherein the fluid printing medium comprises metallic particles, and a liquid binder or an activator.

7. The method as claimed in claim 1, wherein the printing device comprises a stencil printer, a screen printer, a pad printer, or a dispenser.

8. The method as claimed in claim 1, in which the at least one selected printing parameter is a squeegee speed, a squeegee force or a snap-off.

9. The method as claimed in claim 1, wherein the rheological property comprises: a viscosity, a shear stress, a loss modulus, or a storage modulus.

10. The method as claimed in claim 1, wherein the rheological property is measured with a process rheometer integrated into the printing device.

11. The method as claimed in claim 1, wherein steps d) and e) are repeated multiple times.

12. The method as claimed in claim 1, wherein determining a favorable value optimizes a target variable predicted using the rheological model.

13. The method as claimed in claim 1, wherein the rheological model is continuously adapted so that, following the individual printing steps aᵢ), a respective target variable for the printing result is measured and compared with the corresponding target variable predicted using the rheological model.

14. The method as claimed in claim 12, wherein the modelled and/or measured target variable comprises an accuracy of compliance with a predefined wetting area to be printed.

15. A production plant for producing electronic assemblies, the production plant comprising:
a printing device with a printing region for receiving one or more substrates to sequentially provide a series of a plurality of printing surfaces to be printed;
a print head for applying a printing medium;
a rheological sensor for measuring a rheological property of the printing medium within the printing device;
a modelling unit programmed to provide a rheological model for execution of individual printing steps aᵢ), wherein the rheological model uses the repeatedly measured rheological property as a variable input parameter;
an evaluation unit programmed to determine a favorable value for a selected printing parameter using the rheological model in accordance with the currently measured rheological property;
and
a setting unit for automatically setting the determined favorable value for the selected printing parameter.
